(19) United States
(12) Patent Application Publication
(10) Pub. No.: US 2018/0375506 A1
(43) Pub. Date: Dec. 27, 2018

(54) SEMICONDUCTOR DEVICE AND ELECTRONIC CONTROL UNIT

(71) Applicant: RENESAS ELECTRONICS CORPORATION, Tokyo (JP)

(72) Inventors: Hidetoshi TANEMURA, Tokyo (JP); Akira UEMURA, Tokyo (JP)

(21) Appl. No.: 15/968,275

(22) Filed: May 1, 2018

(30) Foreign Application Priority Data
Jun. 26, 2017 (JP) 2017-124075

(51) Int. Cl. H03K 17/14; H05B 37/02; H05B 39/04; G01R 31/26; G01R 31/00

(52) U.S. Cl. CPC H03K 17/145; H05B 37/0227; H01L 29/7827; G01R 31/2628; G01R 31/007; H05B 39/041

(57) ABSTRACT

A hot sensor detects a temperature of an output transistor and a cold sensor detects a temperature of a position distant from the output transistor. When the temperature of the hot sensor rises more than a reference temperature, a temperature detecting circuit asserts an overtemperature detecting signal, and when a temperature difference between the hot sensor and the cold sensor is more than a reference temperature difference, the above circuit asserts the temperature difference detecting signal. A current limiting circuit generates a limited current signal sequentially variable with the negative temperature characteristic for the temperature of the cold sensor and controls a drive current of the output transistor to a current value depending on the signal level of the limited current signal when the overtemperature detecting signal is asserted.

### CROSS-REFERENCE TO RELATED APPLICATIONS

The disclosure of Japanese Patent Application No. 2017-124075 filed on Jun. 26, 2017 including the specification, drawings and abstract is incorporated herein by reference in its entirety.

### BACKGROUND

The invention relates to a semiconductor device and an electronic control unit, and particularly, for example, to a semiconductor device provided with a temperature protection function.

Japanese Unexamined Patent Application Publication No. 2016-72935 discloses a system of limiting a current flowing in an output transistor when a temperature difference between the temperature of the output transistor and its peripheral temperature exceeds a predetermined reference temperature and when the temperature of the output transistor exceeds a predetermine reference temperature.

### SUMMARY

For example, an electronic control unit (ECU: Electronic Control Unit) such as a vehicle device generally mounts a semiconductor device called Intelligent Power Device (IPD). The IPD is integrally formed by an output transistor of driving a load and various protection functions of the output transistor. One of the protection functions is, for example, a temperature protection function as indicated in Japanese Unexamined Patent Application Publication No. 2016-72935.

In recent years, with the progress of reduction in chip size, the IPD requires driving many kinds of loads. Therefore, electric power density in driving load is increased, into a state of easily activating a temperature protection function. When the temperature protection function works, a control to limit the driving ability of the load is generally performed. In this case, a restricted amount of the driving ability sometimes changes rapidly depending on the peripheral temperature. As the result, an excessive limit of the driving ability occurs, which may cause a situation unable to fully drive many kinds of loads.

The embodiment described later is made taking the above into consideration and other objects and novel characteristics will be apparent from the description of the specification and the attached drawings.

A semiconductor device according to one embodiment includes an output transistor, a hot sensor, a cold sensor, a temperature detecting circuit, and a current limiting circuit. The output transistor supplies a drive current to an external load. The hot sensor detects a temperature of the output transistor, and the cold sensor detects a temperature of a position distant from the output transistor. When the temperature of the hot sensor rises more than a reference temperature, the temperature detecting circuit asserts an overtemperature detecting signal and when a temperature difference between the hot sensor and the cold sensor is more than a reference temperature difference, it asserts a temperature difference detecting signal. The current limiting circuit generates a limited current signal sequentially variable with negative temperature characteristic for the temperature of the cold sensor, and controls a drive current of the output transistor to a current value depending on the signal level of the limited current signal when an overtemperature detecting signal is asserted.

According to the embodiment, it is possible to improve a balance between the safety for the temperature and the limit of the driving ability.

### BRIEF DESCRIPTION OF THE DRAWINGS

FIG. 1 is a schematic view showing a constitutional example of a vehicle to which an electronic control unit according to a first embodiment of the invention is applied.

FIG. 2 is a schematic view showing a constitutional example of the electronic control unit according to the first embodiment of the invention.

FIG. 3 is a schematic view showing a constitutional example of a semiconductor device according to the first embodiment of the invention.

FIG. 4 is a view showing an operation example of a current limiting circuit in FIG. 3.

FIG. 5 is a circuit diagram showing a detailed constitutional example of the current limiting circuit and its periphery in FIG. 3.

FIG. 6 is a view showing one example of a relation between the limited current signal and the peripheral temperature in the current limiting circuit in FIG. 5.

FIG. 7 is a waveform chart showing a schematic operation example at an overtemperature detecting time in the semiconductor device of FIG. 3.

FIG. 8 is a circuit diagram showing a detailed constitutional example of the current limiting circuit in FIG. 3, in a semiconductor device according to a second embodiment of the invention.

FIG. 9A is a circuit diagram showing a basic constitutional example of a bandgap reference circuit in FIG. 8 and FIG. 9B is a complementary view showing the operation example of FIG. 9A.

FIG. 10 is a schematic view showing a constitutional example of a semiconductor device as a comparison example in the invention.

FIG. 11 is a circuit diagram showing a constitutional example of a temperature detecting circuit in FIG. 10.

FIG. 12 is a circuit diagram showing a constitutional example of a temperature difference detecting current limiting circuit in FIG. 10.

FIG. 13 is a view showing an arrangement constitutional example of a hot sensor and a cold sensor in FIG. 11.

FIG. 14A is a waveform chart showing a schematic operation example at a temperature difference detecting time in the semiconductor device of FIG. 10, and FIG. 14B is a waveform chart showing a schematic operation example at an overtemperature detecting time in the semiconductor device of FIG. 10.

FIG. 15 is an explanatory view showing one example of a relation between the temperature difference detecting operation and overtemperature detecting operation and the peripheral temperature in the semiconductor device of FIG. 10.

FIG. 16 is an explanatory view showing one example of a relation between a limited current value and a peripheral temperature in the semiconductor device of FIGS. 10 and 15.

FIG. 17 is a waveform chart showing one example of an ideal temporal change of the drive current in driving a light as a load.

FIG. 18A is a waveform chart showing one example of the temporal change of the hot temperature when the peripheral temperature is lower than the boundary temperature, in the case of driving the light using the semiconductor device of FIG. 10, and FIG. 18B is a waveform chart showing one example of the temporal change of the drive current in the case of FIG. 18A.

FIG. 19A is a waveform chart showing one example of the temporal change of the hot temperature when the peripheral temperature is higher than the boundary temperature, in the case of driving the light according to the semiconductor device of FIG. 10, and FIG. 19B is a waveform chart showing one example of the temporal change of the drive current in the case of FIG. 19A.

### DETAILED DESCRIPTION

In the following embodiments, a description will be made by dividing into a plurality of sections or embodiments when necessary for the convenience sake, these are not unrelated to each other but are related to each other such that one covers some or all of modified examples, details, supplemental explanation and so forth of the other unless otherwise clearly specified. In addition, in the following embodiments, when the number of elements (including the number of units, a numerical value, an amount, a range and the like) is referred to, it is not limited to the specific number but may be more than or not more than the specific number unless otherwise clearly specified and unless otherwise definitely restricted to the specific number in principle.

In addition, in the following embodiments, the constitutional element (including an element step) is not necessarily indispensable unless otherwise clearly specified and unless otherwise thought to be clearly indispensable in principle. Similarly, in the following embodiments, when the shapes of the constitutional elements and their positional relationship are referred to, the ones that are substantially approximate or similar to the shapes will be included unless otherwise clearly specified and unless otherwise clearly thought that it is not so in principle. The same also applies to the above-mentioned number and range.

The circuit elements forming each function block in the embodiment are formed on a semiconductor substrate of single crystal silicon, according to the well-known integrated circuit technique such as the complementary MOS (CMOS) transistor although not restricted to this. In the specification, an n-channel typed Metal Oxide Semiconductor Field Effect Transistor (MOSFET) is referred to as an nMOS transistor and a p-channel typed Metal Oxide Semiconductor Field Effect Transistor (MOSFET) is referred to as a pMOS transistor.

Hereinafter, the embodiments of the invention will be described in detail based on the drawings. In all the drawings for describing the embodiments, the same reference codes are attached to the same members in principle and the repeated description is omitted.

### First Embodiment

### «Outline of Electronic Control Unit»

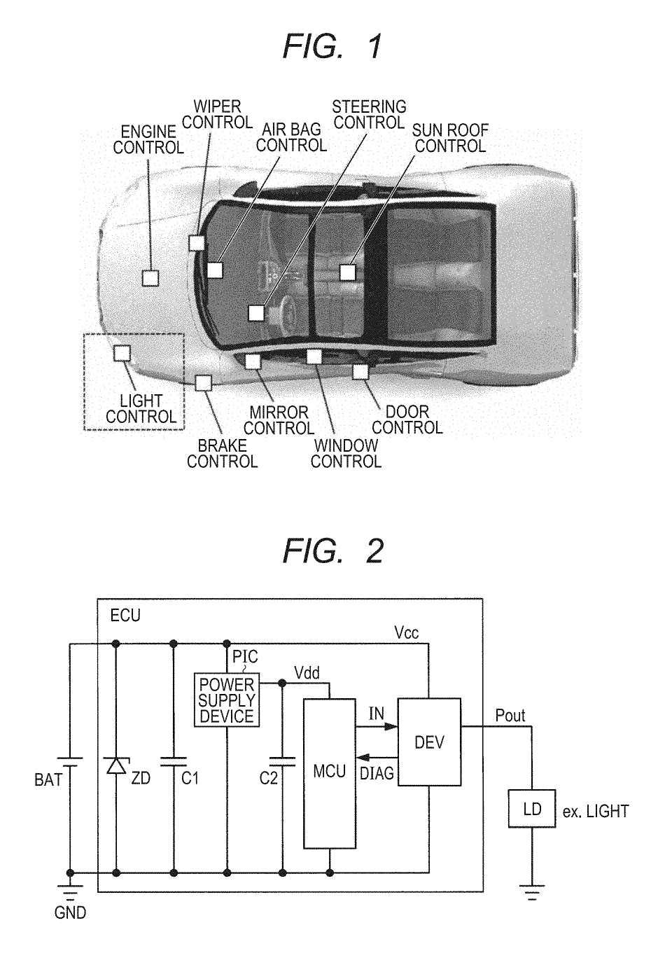

FIG. 1 is a schematic view showing a constitutional structure of a vehicle to which the electronic control unit according to a first embodiment of the invention is applied. As shown in FIG. 1, the electronic control unit mounted on the vehicle (typically, automobile) performs various controls such as engine control, wiper control, air bag control, steering control, sunroof control, light control, brake control, mirror control, window control, and door control.

FIG. 2 is a schematic view showing a constitutional example of the electronic control unit according to the first embodiment of the invention. The electronic control unit ECU shown in FIG. 2 works, for example, as the light control shown in FIG. 1. The electronic control unit ECU is formed by mounting a semiconductor device DEV, a microcontroller MCU, a power supply device PIC, condensers C1 and C2 and a Zener diode ZD on a wiring substrate.

The microcontroller MCU includes, for example, a Central Processing Unit (CPU) and a memory, various kinds of analog peripheral circuits such as Analog to Digital Converter (ADC), and various kinds of digital peripheral circuits such as communication interface, to realize a predetermined function depending on a user. The semiconductor device DEV is an IPD, to drive a load LD (here, light) according to the instruction (here, an external input signal IN) from the microcontroller MCU. Further, the semiconductor device DEV properly outputs the states of various protection circuits and the self-diagnosis result DIAG to the microcontroller MCU.

The electronic control unit ECU receives a power voltage Vcc, for example, about 12 V, with the ground power voltage GND of 0 V as reference, from an external battery BAT. The condenser C1 holds the power voltage Vcc and the Zener diode ZD limits the voltage level of the power voltage Vcc. The power supply device PIC generates an internal power voltage Vdd of 5 V from the power voltage Vcc, and the condenser C2 holds the internal power voltage Vdd. The microcontroller MCU operates with the internal power voltage Vdd.

Here, the semiconductor device DEV actually controls a plurality of lights in some cases, and depending on the case, several types of lights such as ahead light and a fog light may be controlled. According as the number of the control targets is increased, the temperature of the semiconductor device DEV is easier to rise according to the load drive. Therefore, the semiconductor device DEV is required to ensure safety against the temperature rise and to achieve the maximum load driving ability within a range capable of ensuring the safety.

### «Structure and Operation of Semiconductor Device (Comparison Example)»

Here, prior to the description of a semiconductor device according to the first embodiment, a semiconductor device examined as the prerequisite will be described. FIG. 10 is a schematic view showing the constitutional example of a semiconductor device as a comparison example of the invention. The semiconductor device DEV′ shown in FIG. 10 includes an output transistor Qd, a driver DRV, a logic circuit LGC′, a temperature detecting circuit DADT, a temperature difference detecting current limiting circuit DTIL, and an overtemperature detecting current limiting circuit ATIL.

The output transistor Qd is an nMOS transistor having a power route (source and drain path) between the power voltage Vcc and the output node Nout, and drives the load (not illustrated) by supplying the power signal Pout (for example, drive current) to the output node Nout. The driver DRV turns on or off the output transistor Qd by applying a predetermined gate voltage Vg to the output transistor Qd. The logic circuit LGC′ controls on the output transistor Qd through a driver DRV according to assertion of an external input signal IN, during a period without any motion of the various types of protection functions.

The temperature detecting circuit DADT monitors the temperature (in the specification, referred to as a hot temperature) of the output transistor Qd by a hot sensor described later, and monitors the peripheral temperature (in the specification, referred to as a cold temperature) by a cold sensor described later. When the hot temperature exceeds a predetermined reference temperature, the temperature detecting circuit DADT asserts an overtemperature detecting signal ATo, and then when the hot temperature is decreased by a predetermined hysteresis temperature, the above circuit negates the overtemperature detecting signal ATo. When a temperature difference between the hot temperature and the cold temperature is larger than a predetermined reference temperature difference, the temperature detecting circuit DADT asserts the temperature difference detecting signal DTo and then when the temperature difference is decreased by the predetermined hysteresis temperature, the above circuit negates the temperature difference detecting signal DTo.

The logic circuit LGC′ respectively latches the assertion levels of the overtemperature detecting signal ATo and the temperature difference detecting signal DTo, and respectively asserts the overtemperature latch signal Sat and the temperature difference latch signal Sdt. Once the assertion of the overtemperature detecting signal ATo occurs, the logic circuit LGC′ keeps the assertion level of the overtemperature latch signal Sat, for example, until the external input signal IN is negated, regardless of the level of the overtemperature detecting signal ATo thereafter. It is the same as for the temperature difference detecting signal DTo.

When one of the overtemperature latch signal Sat and the temperature difference latch signal Sdt is asserted, the temperature difference detecting current limiting circuit DTIL lowers the gate voltage Vg of the output transistor Qd, hence to limit the drive current of the output transistor Qd. When the overtemperature latch signal Sat is asserted, the overtemperature detecting current limiting circuit ATIL lowers the gate voltage Vg of the output transistor Qd, hence to limit the drive current of the output transistor Qd. In other words, when the overtemperature latch signal Sat is asserted, both the temperature difference detecting current limiting circuit DTIL and the overtemperature detecting current limiting circuit ATIL limit the current and the drive current is much more limited than when the temperature difference latch signal Sdt is asserted.

When the external input signal IN is at an assertion level, the logic circuit LGC′ outputs an inversion signal of the overtemperature detecting signal ATo to the driver DRV, to control on and off the output transistor Qd so that the hot temperature may be limited to a predetermined reference temperature. Similarly, when the external input signal IN is at the assertion level, the logic circuit LGC′ outputs the inversion signal of the temperature difference detecting signal DTo to the driver DRV, to control on and off the output transistor Qd so that the temperature difference may be limited to a predetermined reference temperature difference. The drive current in controlling on the output transistor Qd is determined depending on the states of the overtemperature latch signal Sat and the temperature difference latch signal Sdt, as mentioned above.

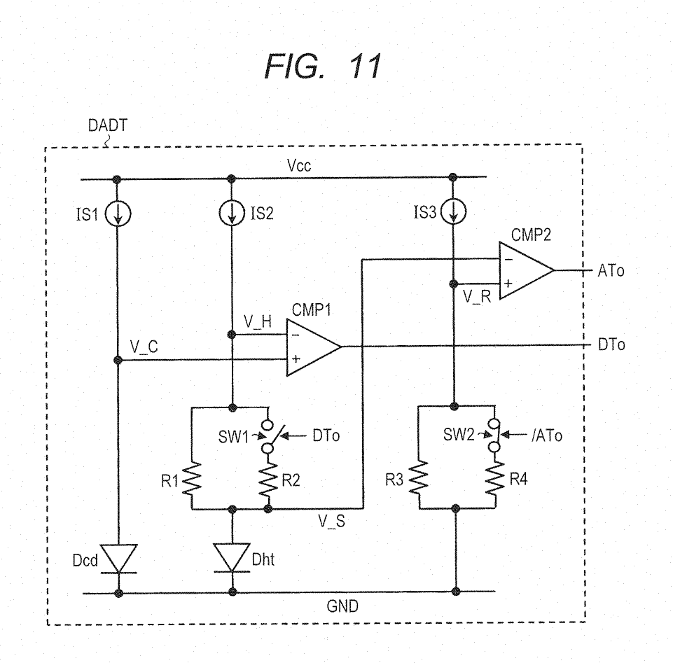

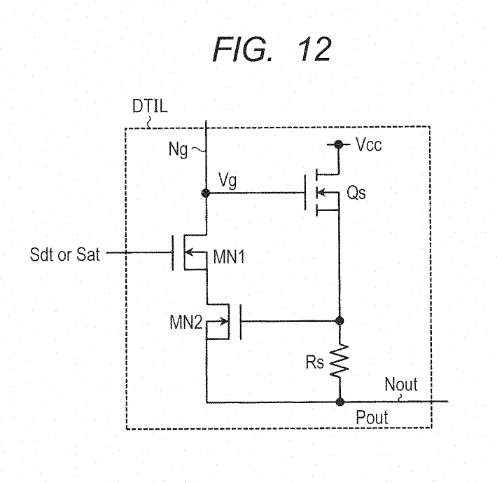

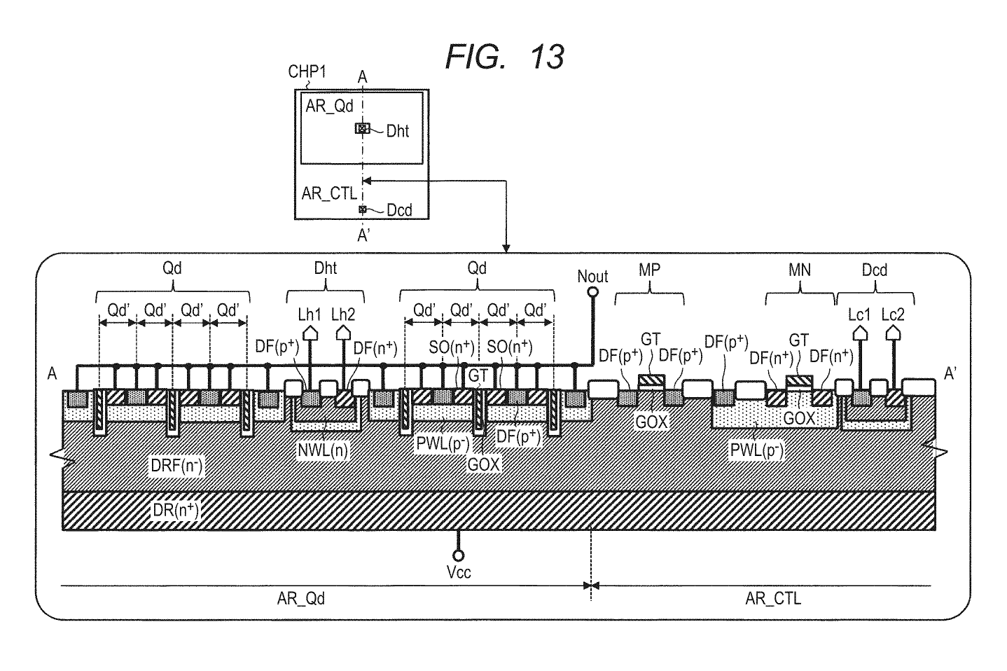

FIG. 11 is a circuit diagram showing a constitutional example of the temperature detecting circuit shown in FIG. 10. FIG. 13 is a view showing an arrangement constitutional example of the hot sensor and the cold sensor in FIG. 11. The temperature detecting circuit DADT shown in FIG. 11 includes diodes Dcd and Dht, constant current sources IS1 to IS3, comparators CMP1 and CMP2, resistance elements R1 to R4, and switches SW1 and SW2. The diode Dcd works as the cold sensor by supplying a constant current from the constant current source IS1. The diode Dht works as the hot sensor by supplying a constant current from the constant current source IS2.

As shown in FIG. 13, a semiconductor chip CHP1 forming the semiconductor device DEV′ includes, for example, a forming region AR_Qd of the output transistor Qd that is the deviated region of the whole chip region and a forming region AR_CTL of the control circuit that is the other region thereof. The hot sensor (that is, the diode Dht) is arranged in the middle portion of the forming region AR_Qd of the output transistor Qd. The cold sensor (that is, the diode Dcd) is arranged in the forming region AR_CTL of the control circuit at a good distance from the forming region AR_Qd of the output transistor Qd.

Here, the temperature of the hot sensor rises more according as the current flowing in the output transistor Qd increases. Here, the generated heat of the output transistor Qd easily concentrates particularly on the middle portion that is the arrangement portion of the hot sensor. On the other hand, it takes a little bit of time until the generated heat of the output transistor Qd is transmitted to the cold sensor because of detecting the temperature at a distance from the output transistor Qd.

The output transistor Qd is formed by a plurality of unit MOS transistors Qd′ coupled in parallel. In this example, although eight unit MOS transistors Qd′ are shown, actually much more unit MOS transistors Qd′ are provided. The unit MOS transistor Qd′ is formed by a vertical nMOS transistor with the main surface as a source and the rear surface as a drain.

The n⁺-type drain diffusion layer DR (n⁺) is arranged on the side of the rear surface and the n⁻-type drift layer DRF (n⁻) is arranged thereon. The drain diffusion layer DR (n⁺) is coupled to the power voltage Vcc. On the other hand, the p⁻-type well PWL (p⁻) that is the channel forming region is arranged on the side of the main surface, and the n⁺-type source diffusion layer SO (n⁺) is formed therein. Further, the p⁺-type diffusion layer DF (p⁺) for power feeding for well is formed in the well PWL (p⁺). The diffusion layer DF (p⁺) and the source diffusion layer SO (n⁺) are both coupled to the output node Nout.

A trench including a gate insulating film GOX and a gate layer GT is formed on the side of the main surface at the position adjacent to the source diffusion layer SO (n⁺) and the well PWL (p⁻). When a predetermined positive voltage is applied to the gate layer GT, an n channel is formed in the well PWL (p⁻), and the source diffusion layer SO (n⁺) conducts with the drift layer DRF (n⁻) and the drain diffusion layer DR (n⁺) through the n channel.

The hot sensor (diode Dht) is formed by the pn junction diode arranged on the side of the main surface. Specifically, the well PWL (p⁻) for insulation is arranged on the side of the main surface and the n-type well NWL (n) is arranged therein. The p⁺-type diffusion layer DF (p⁺) and the n⁺-type diffusion layer DF (n⁺) are formed within the well NWL (n). The diffusion layer DF (p⁺) is coupled to the anode wiring Lh1 and the diffusion layer DF (n⁺) is coupled to the cathode wiring Lh2.

On the other hand, a pMOS transistor MP and an nMOS transistor MN are properly arranged in the forming region AR_CTL of the control circuit. The pMOS transistor MP is provided with two diffusion layers DF (p⁺) as the source and the drain on the side of the main surface, and provided with the gate layer GT therebetween through the gate insulating film GOX. The nMOS transistor MN is provided with the p-type well PWL (p⁻) on the side of the main surface, provided with two diffusion layers DF (n⁺) as the source and the drain in the well, and provided with the gate layer GT therebetween through the gate insulating film GOX. Further, the cold sensor (diode Dcd) having the same structure as the hot sensor is arranged in the forming region AR_CTL of the control circuit. The diffusion layer DF (p⁺) of the diode Dcd is coupled to the anode wiring Lc1 and the diffusion layer DF (n⁺) of the diode Dcd is coupled to the cathode wiring Lc2.

Although the illustration is omitted, more specifically, on the side of the main surface, a source electrode is arranged in the forming region AR_Qd of the output transistor Qd, spreading on the whole surface thereof and the output node Nout is coupled to the source electrode. Further, the anode wiring Lh1 and the cathode wiring Lh2 are drawn toward the forming region AR_CTL of the control circuit by providing a space in a part of the source electrode.

Returning to FIG. 11, a voltage V_C is applied to a positive input node (+) and a voltage V_H is applied to a negative input node (−) in a comparator CMP1 and as a comparison result, a temperature difference detecting signal DTo is output. The voltage V_C is an output voltage from the anode of the diode Dcd, having negative temperature characteristic. A resistance element R2 and a switch SW1 are coupled in series and the series circuit and a resistance element R1 are coupled in parallel. The parallel circuit is provided between a negative input node (−) of the comparator CMP1 and the anode of the diode Dht. The voltage V_H is generated by the series circuit of the above parallel circuit and the diode Dht, having the negative temperature characteristic. The switch SW1 is controlled on during the assertion period of the temperature difference detecting signal DTo.

A voltage V_R is applied to the positive input node (+) and a voltage V_S is applied to the negative input node (−) in the comparator CMP2 and as a comparison result, an overtemperature detecting signal ATo is output. The voltage V_S is an output voltage from the anode of the diode Dht, having the negative temperature characteristic. A resistance element R4 and a switch SW2 are coupled in series, and this series circuit and a resistance element R3 are coupled in parallel. A voltage V_R is generated by the parallel circuit, actually not having the temperature dependency. The switch SW2 is controlled on during the negate period of the overtemperature detecting signal ATo.

In this structure, the initial state is adjusted to be voltage V_H≥voltage V_C. In this state, the comparator CMP1 controls the temperature difference detecting signal DTo to an “L” level (negate level), the switch SW1 is turned off and the output transistor Qd in FIG. 10 is turned on. According to the drive of the load LD, the temperature (specifically, hot temperature) of the output transistor Qd rises, a temperature difference between the hot temperature and the cold temperature is enlarged, and the voltage V_H drops at a larger slant than the voltage V_C. When the temperature difference is enlarged up to voltage V_H<voltage V_C (in short, when the temperature difference gets larger than the reference temperature difference), the comparator CMP1 controls the temperature difference detecting signal DTo to an “H” level (assertion level).

When the temperature difference detecting signal DTo is asserted, the switch SW1 is turned on from off, and according to this, the voltage V_H drops in a moment. The drop of this voltage V_H becomes a hysteresis voltage, and the temperature corresponding to this voltage becomes a hysteresis temperature. On the other hand, according to the assertion of the temperature difference detecting signal DTo, the output transistor Qd is turned off. As the result, the hot temperature drops, the temperature difference between the hot temperature and the cold temperature is reduced, and the voltage V_H rises. When the temperature difference is reduced to voltage V_H≥voltage V_C (in short, the temperature difference gets smaller by the hysteresis temperature), the comparator CMP1 controls the temperature difference detecting signal DTo to the “L” level (negate level). According to this, the operation is returned to the initial state.

The initial state is adjusted to be voltage V_S≥voltage V_R. In this state, the comparator CMP2 controls the overtemperature detecting signal ATo to the “L” level (negate level), the switch SW2 is turned on and the output transistor Qd is turned on. According to the drive of the load LD, the hot temperature rises and the voltage V_S drops. When the hot temperature rises up to voltage V_S<voltage V_R (in short, when the hot temperature rises up more than the reference temperature), the comparator CMP2 controls the overtemperature detecting signal ATo to the “H” level (assertion level).

When the overtemperature detecting signal ATo is asserted, the switch SW2 is turned off from on, and according to this, the voltage V_R rises in a moment. This rise of the voltage V_R becomes the hysteresis voltage and the temperature corresponding to the same voltage becomes the hysteresis temperature. On the other hand, according to the assertion of the overtemperature detecting signal ATo, the output transistor Qd is turned off. As the result, the hot temperature drops and the voltage V_S rises. When the hot temperature drops to voltage V_S≥voltage V_R (in short, when the hot temperature drops by the hysteresis temperature), the comparator CMP2 controls the overtemperature detecting signal ATo to the “L” level (negate level). According to this, the operation is returned to the initial state.

As mentioned above, by providing the output transistor Qd with the hysteresis characteristic, the output transistor Qd stops the power supply operation according to the assertion of the temperature difference detecting signal DTo or the overtemperature detecting signal ATo and thereafter, resumes the power supply operation when the temperature drops enough. As the result, the output transistor Qd can be fully protected.

FIG. 12 is a circuit diagram showing the temperature difference detecting current limiting circuit in FIG. 10. The temperature difference detecting current limiting circuit DTIL shown in FIG. 12 includes a sense transistor Qs, nMOS transistors MN1 and MN2, and a sense resistance element Rs. The sense transistor Qs has 1/n transistor size of the output transistor Qd (for example, one-several thousandth), and is driven with the same gate voltage Vg as the output transistor Qd. The sense resistance element Rs converts the current flowing to the sense transistor Qs into sense voltage. As the result, according as the current flowing to the output transistor Qd gets larger, the sense voltage becomes larger.

The nMOS transistor MN2 is controlled by the sense voltage. As the result, the on-resistance of the nMOS transistor MN2 gets smaller according as the current flowing to the output transistor Qd gets larger. When the temperature difference latch signal Sdt or the overtemperature latch signal Sat is at the assertion level, the nMOS transistor MN1 is controlled on. According to this, when the temperature difference latch signal Sdt or the overtemperature latch signal Sat is at the assertion level, the gate electric charges of the output transistor Qd are discharged through the nMOS transistors MN1 and MN2, and therefore, the drive current of the output transistor Qd is limited. Although the illustration is omitted, the overtemperature detecting current limiting circuit ATIL in FIG. 10 has the same structure as the temperature difference detecting current limiting circuit DTIL.

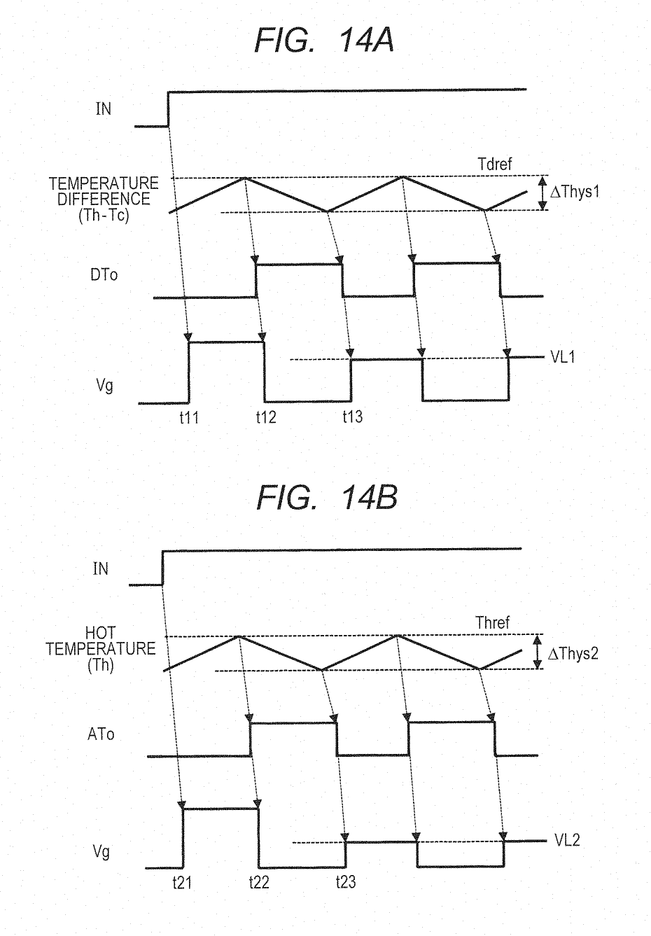

FIG. 14A is a waveform chart showing a schematic operation example at a temperature difference detecting time in the semiconductor device of FIG. 10, and FIG. 14B is a waveform chart showing a schematic operation example at an overtemperature detecting time in the semiconductor device of FIG. 10. As shown in FIG. 14A, the gate voltage Vg of the output transistor Qd is controlled to the on level according to the “H” level of the external input signal IN and the “L” level of the temperature difference detecting signal DTo (timing t11). According to this, the temperature difference between the hot temperature Th and the cold temperature Tc is enlarged, and when it gets larger than the reference temperature difference Tdref, the temperature difference detecting signal DTo becomes the “H” level and the gate voltage Vg is controlled to the off level (timing t12).

As the result, the temperature difference between the hot temperature Th and the cold temperature Tc is reduced, and when it gets smaller by the hysteresis temperature ΔThys1, the temperature difference detecting signal DTo becomes the “L” level and the gate voltage Vg is controlled again to the on level (timing t13). The on level of the gate voltage Vg here is controlled to the voltage value VL1 lower than in the case of the timing t11, according to the operation of the temperature difference detecting current limiting circuit DTIL. According to this, the drive current of the output transistor Qd is limited.

Also in FIG. 14B, similarly, the gate voltage Vg of the output transistor Qd is controlled to the on level according to the “H” level of the external input signal IN and the “L” level of the overtemperature detecting signal ATo (timing t21). According to this, the hot temperature Th rises and when it gets more than the reference temperature Thref, the overtemperature detecting signal ATo becomes the “H” level and the gate voltage Vg is controlled to the off level (timing t22).

As the result, the hot temperature Th drops and when it gets lower by the hysteresis temperature ΔThys2, the overtemperature detecting signal ATo becomes the “L” level and the gate voltage Vg is controlled to the on level again (timing t23). The on level of the gate voltage Vg here is controlled to the voltage value VL2 lower than in the case of the timing t21 and lower than the voltage value VL1 in FIG. 14A, according to the operation of the temperature difference detecting current limiting circuit DTIL and the overtemperature detecting current limiting circuit ATIL. According to this, the drive current of the output transistor Qd is further limited than in the case of FIG. 14A.

«Relation between Temperature Difference Detecting Operation/Overtemperature Detecting Operation and Peripheral Temperature»

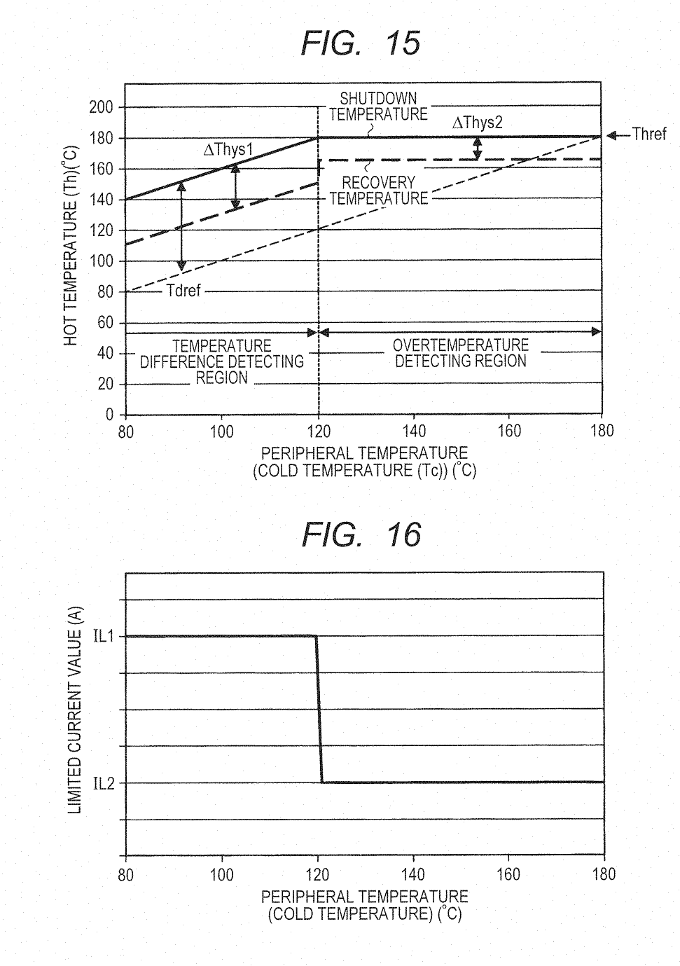

FIG. 15 is a view showing one example of a relation between the temperature difference detecting operation and overtemperature detecting operation and the peripheral temperature in the semiconductor device of FIG. 10. In the example of FIG. 15, the reference temperature difference Tdref and the hysteresis temperature ΔThys1 in the temperature difference detecting operation are respectively 60° C. and 30° C., and the reference temperature Thref and the hysteresis temperature ΔThys2 in the overtemperature detecting operation are respectively 180° C. and 15° C.

When the peripheral temperature (namely, the cold temperature Tc) is 100° C., the temperature difference detecting signal DTo is asserted at the hot temperature Th of 160° C., and when the hot temperature Th is decreased to 130° C., the above signal is negated. When the cold temperature Tc is 150° C., the overtemperature detecting signal ATo is asserted at the hot temperature Th of 180° C., and when the hot temperature Th is reduced to 165° C., the above is negated.

In this temperature setting, when the cold temperature Tc is lower than the boundary temperature with 120° C. as the boundary temperature, the temperature difference detecting operation is performed. In this case, the temperature difference detecting signal DTo is asserted at the hot temperature Th less than 180° C. When the temperature difference detecting signal DTo is asserted, as shown in FIG. 14A, a control operation is performed so that the temperature difference may not exceed 60° C. (in other words, to keep the hot temperature Th less than 180° C.). As the result, actually the overtemperature detecting operation is not performed.

On the other hand, when the cold temperature Tc is higher than the boundary temperature (120° C.), the overtemperature detecting operation is performed. The overtemperature detecting signal ATo is asserted at the temperature difference less than 60° C. When the overtemperature detecting signal ATo is asserted, as shown in FIG. 14B, a control operation is performed so that the hot temperature may not exceed 180° C. (in other words, to keep the temperature difference less than 60° C.). As the result, actually, the temperature difference detecting operation is not performed.

FIG. 16 is an explanatory view showing one example of a relation between the limited current value and the peripheral temperature in the semiconductor device of FIGS. 10 and 15. As shown in FIG. 16, when the temperature difference detecting signal DTo is asserted with the cold temperature Tc in a range less than the boundary temperature (120° C.), the drive current of the output transistor Qd is limited to the current value ILL On the other hand, when the overtemperature detecting signal ATo is asserted with the cold temperature Tc in a range more than the boundary temperature (120° C.), the drive current of the output transistor Qd is limited to the current value IL2 less than the current value ILL The current values IL1 and IL2 are the current values respectively corresponding to the voltage values VL1 and VL2 in FIGS. 14A and 14B.

### «Problem of Semiconductor Device (Comparison Example)»

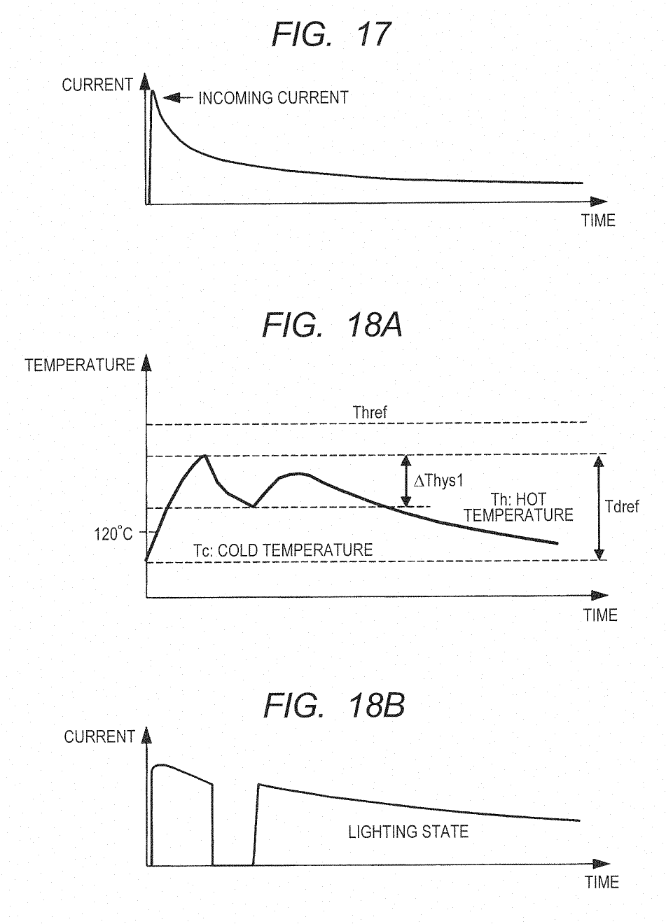

FIG. 17 is a waveform chart showing one example of an ideal temporal change of the drive current in driving a light as a load. As shown in FIG. 17, when driving the light as the load LD, since the resistance of a filament within the light is very small in the initial driving, a very large drive current flows in the light. Thereafter, when the temperature of the filament rises according to the drive current, the resistance value of the filament is increased and the drive current flowing in the light is reduced.

FIG. 18A is a waveform chart showing one example of the temporal change of the hot temperature when the peripheral temperature is lower than the boundary temperature, in the case of driving the light using the semiconductor device in FIG. 10, and FIG. 18B is a waveform chart showing one example of the temporal change of the drive current in the case of FIG. 18A.

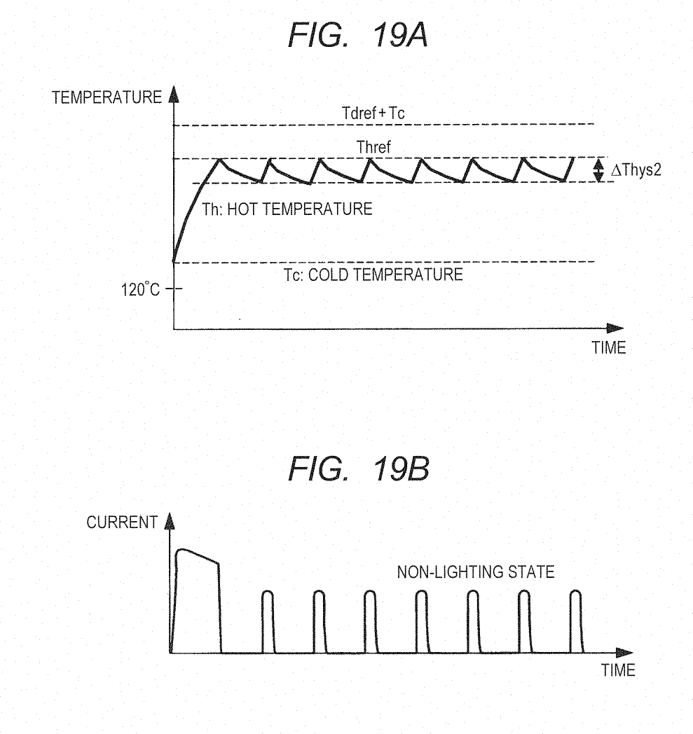

FIG. 19A is a waveform chart showing one example of the temporal change of the hot temperature when the peripheral temperature is higher than the boundary temperature, in the case of driving the light according to the semiconductor device in FIG. 10, and FIG. 19B is a waveform chart showing one example of the temporal change of the drive current in the case of FIG. 19A.

As mentioned above, in the initial driving, the temperature of the filament rapidly rises. Consequently, there is a high possibility that the temperature difference detecting signal DTo or the overtemperature detecting signal ATo is asserted according to the cold temperature Tc. In the example of FIG. 18A, since the cold temperature Tc is lower than the boundary temperature (120° C.), the temperature difference detecting signal DTo is asserted. According to this, the drive current is limited to the current value IL1 of FIG. 16. The current value IL1 is large enough to drive the light; as the result, the light is in a stable lighting state in FIG. 18B.

On the other hand, in the example of FIG. 19A, since the cold temperature Tc is higher than the boundary temperature (120° C.), the overtemperature detecting signal ATo is asserted. According to this, the drive current is limited to the current value IL2 of FIG. 16. The current value IL2 is not large enough to drive the light; as the result, the light is in a non-lighting state in FIG. 19B.

According to this, when using the constitutional example of FIG. 10, the limited amount of the driving ability (here, the drive current) rapidly changes, depending on whether the cold temperature Tc is lower (for example, 119° C.) or higher (for example, 121° C.) than the boundary temperature (120° C.). As the result, even a small change of the cold temperature Tc causes a big difference in the driving state of the load (lighting state of the light). Then, for example, the current value IL2 is considered to be enlarged. If so, for example, when especially the cold temperature Tc is high in the hysteresis control as shown in FIG. 14B, the temperature of the output transistor Qd may rise excessively according to the overshoot. As the result, there is a fear of reducing the safety of the output transistor Qd.

### «Structure and Operation of Semiconductor Device (First Embodiment)»

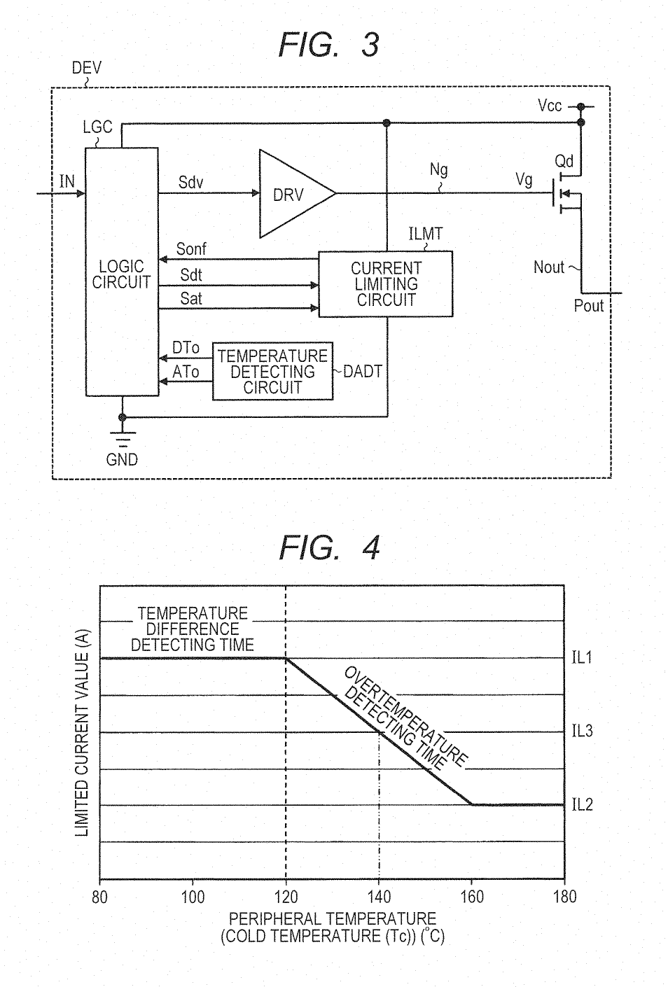

FIG. 3 is a schematic view showing a constitutional example of a semiconductor device according to the first embodiment of the invention. FIG. 4 is a view showing an operation example of a current limiting circuit in FIG. 3. The semiconductor device DEV shown in FIG. 3 includes an output transistor Qd, a driver DRV, a logic circuit LGC, a temperature detecting circuit DADT, and a current limiting circuit ILMT. The structure and the operation of the output transistor Qd, the driver DRV, and the temperature detecting circuit DADT are the same as those in the case of FIG. 10.

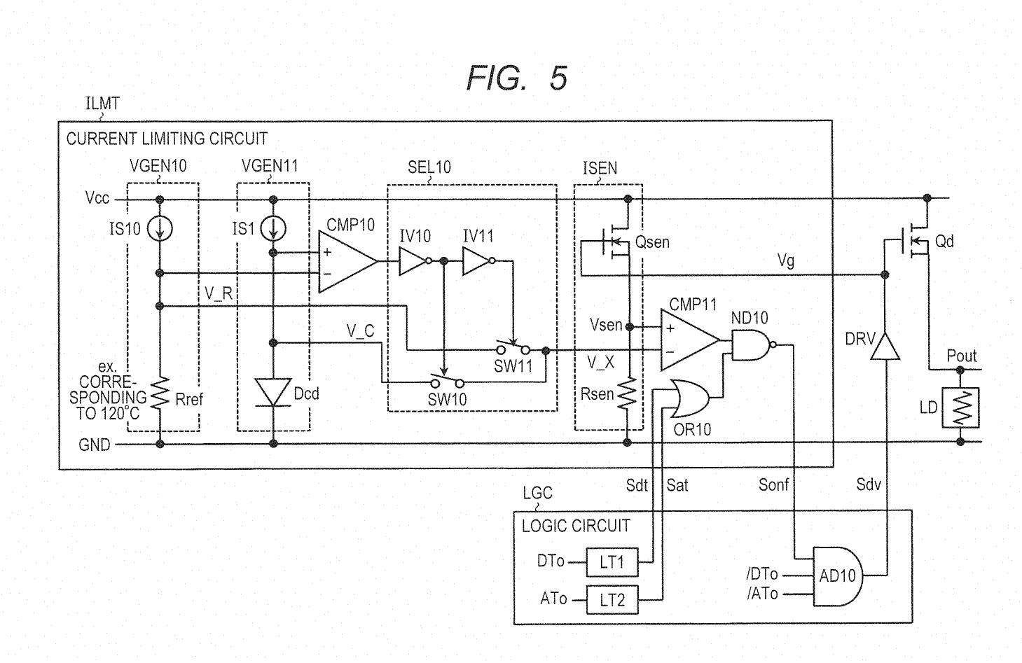

The current limiting circuit ILMT generates a limited current signal (V_X described in FIG. 5) sequentially changing with the negative temperature characteristic for the cold temperature Tc, as shown in FIG. 4, different from two discrete values in the case of FIG. 16. Specifically, the current limiting circuit ILMT generates the limited current signal (V_X) sequentially changing with the negative temperature characteristic in the temperature range in which the cold temperature Tc is higher than the boundary temperature (120° C.) and having a constant signal level for the cold temperature Tc in the temperature range in which the cold temperature Tc is lower than the boundary temperature.

When the overtemperature detecting signal ATo is asserted (specifically, when the overtemperature latch signal Sat is asserted), the current limiting circuit ILMT limits the drive current of the output transistor Qd to the current value depending on the signal level of the limited current signal (V_X). Similarly, when the temperature difference detecting signal DTo is asserted (specifically, when the temperature difference latch signal Sdt is asserted), the current limiting circuit ILMT limits the drive current of the output transistor Qd to the current value depending on the signal level of the limited current signal (V_X). In FIG. 4, for example, when the cold temperature is 140° C., the drive current is limited to the current value IL3 and when it is 100° C., the drive current is limited to the current value IL1.

In the current limit, the current limiting circuit ILMT generates, for example, an on and off control signal Sconf for controlling on and off the output transistor Qd. The logic circuit LGC controls on and off the output transistor Qd, using a driver control signal Sdv through the driver DRV. The driver control signal Sdv is generated based on the temperature difference detecting signal DTo and the overtemperature detecting signal ATo, similarly to the case of FIG. 10, and additionally, based on the on and off control signal Sonf. Specifically, the drive current in the period of controlling on the output transistor Qd based on the temperature difference detecting signal DTo and the overtemperature detecting signal ATo is limited based on the duty of the on and off control signal Sonf.

### «Detail of Current Limiting Circuit and its Vicinity»

FIG. 5 is a circuit diagram showing the detailed constitutional example of the current limiting circuit and its vicinity. In FIG. 5, the current limiting circuit ILMT includes voltage generating circuits VGEN10 and VGEN11, comparators CMP10 and CMP11, a selecting circuit SEL10, a current sense circuit ISEN, a NAND gate ND10, and OR gate OR10. Further, the logic circuit LGC includes latch circuits LT1 and LT2 and an AND gate AD10.

In the current limiting circuit ILMT, the voltage generating circuit VGEN10 includes a resistance element Rref to which a constant current from the constant current source IS10 is supplied and generates a constant voltage V_R corresponding to the boundary temperature (120° C.). The voltage generating circuit VGEN11 includes a diode Dcd to which the constant current from the constant current source IS1 is supplied and generates a voltage V_C sequentially changing with the negative temperature characteristic for the cold temperature Tc.

The comparator CMP10 compares the voltage V_R from the voltage generating circuit VGEN10 with the voltage V_C from the voltage generating circuit VGEN11. In other words, the comparator CMP10 determines whether the cold temperature Tc is higher or lower than the boundary temperature (120° C.). In this example, the voltage generating circuit VGEN11 is shared with the cold sensor within the temperature detecting circuit DADT in FIG. 11. According to this, the circuit size is reduced and further, the comparison between the cold temperature and the boundary temperature by the comparator CMP10 can be performed at a high accuracy. Depending on the cases, the respective individual diodes Dcd may be provided in the voltage generating circuit VGEN11 and the temperature detecting circuit DADT, in order to optimize the respective constant current values. In this case, for example, two diodes Dcd may be formed adjacently in the forming region of the diode Dcd shown in FIG. 13.

The selecting circuit SEL10 includes inverters IV10 and IV11 and switches SW10 and SW11 and outputs the voltage V_R from the voltage generating circuit VGEN10 or the voltage V_C from the voltage generating circuit VGEN11 as the limited current signal V_X, depending on the comparison result of the comparator CMP10. In this example, when voltage V_C voltage V_R (when the cold temperature Tc is the boundary temperature or less), the switch SW11 is turned on and the voltage V_R is output as the limited current signal V_X. On the other hand, when voltage V_C<voltage V_R (when the cold temperature Tc is higher than the boundary temperature), the switch SW10 is controlled on and the voltage V_C is output as the limited current signal V_X.

The current sense circuit ISEN includes a sense transistor Qsen and a sense resistance element Rsen, detects the drive current flowing in the output transistor Qd, and generates a sense voltage Vsen in proportion to the size of this drive current. The sense transistor Qsen has the 1/n transistor size (for example, one-several thousandth) of the output transistor Qd and is driven with the same gate voltage Vg as that of the output transistor Qd. The sense transistor Qsen is formed, for example, by using a part of many unit MOS transistors Qd′ in FIG. 13.

When the load LD is regarded as the resistance element, the source voltage of the sense transistor Qsen fluctuates in accordance with the source voltage of the output transistor Qd together with the sense resistance element Rsen. According to this, the output transistor Qd and the sense transistor Qsen actually form a current mirror circuit. The sense resistance element Rsen converts the current flowing in the sense transistor Qs into the sense voltage Vsen.

The comparator CMP11 compares the sense voltage Vsen from the current sense circuit ISEN with the limited current signal V_X, to control on and off the output transistor Qd according to the comparison result. Specifically, when sense voltage Vsen<limited current signal V_X (when the drive current is smaller than the limited current value), the comparator CMP11 controls on the output transistor Qd by outputting the “L” level. On the other hand, when sense voltage Vsen≥limited current signal V_X (when the drive current is the limited current value or more), the comparator CMP11 controls off the output transistor Qd by outputting the “H” level.

Specifically, the output signal of the comparator CMP11 becomes the on and off control signal Sonf through the NAND gate ND10 and the driver control signal Sdv through the AND gate AD10 within the logic circuit LGC. More specifically, as mentioned in FIG. 10, the logic circuit LGC latches the assertion levels of the temperature difference detecting signal DTo and the overtemperature detecting signal ATo respectively using the latch circuits LT1 and LT2, and controls the temperature difference latch signal Sdt and the overtemperature latch signal Sat to the respective assertion levels (“H” level). When the temperature difference latch signal Sdt or the overtemperature latch signal Sat is at the assertion level, the OR gate OR10 outputs the “H” level. In this case, the NAND gate ND10 inverts the output signal of the comparator CMP11 and outputs it as the on and off control signal Sonf.

In other words, when the temperature difference latch signal Sdt or the overtemperature latch signal Sat is at the assertion level and the drive current is less than the limited current value, the on and off control signal Sonf becomes the “H” level, and when the drive current is the limited current value or more, it becomes the “L” level. On the other hand, when both the temperature difference latch signal Sdt and the overtemperature latch signal Sat are at the negate level, the on and off control signal Sonf is fixed at the “H” level.

The AND gate AD10 outputs the driver control signal Sdv according to the AND operation result of the on and off control signal Sonf, the inversion signal (/DTo) of the temperature difference detecting signal, and the inversion signal (/ATo) of the overtemperature detecting signal. As the result, the driver control signal Sdv becomes the “L” level during the period of asserting at least one of the temperature difference detecting signal DTo and the overtemperature detecting signal ATo and the output transistor Qd is controlled off. On the other hand, the driver control signal Sdv becomes equal to the on and off control signal Sonf during the period of negating both the temperature difference detecting signal DTo and the overtemperature detecting signal ATo and the output transistor Qd is controlled on and off depending on the “H” level and “L” level of the on and off control signal Sonf. When both the temperature difference latch signal Sdt and the overtemperature latch signal Sat are at the negate level, the output transistor Qd is fixed to on, without current limit, because of the on and off control signal Sonf fixed to the “H” level.

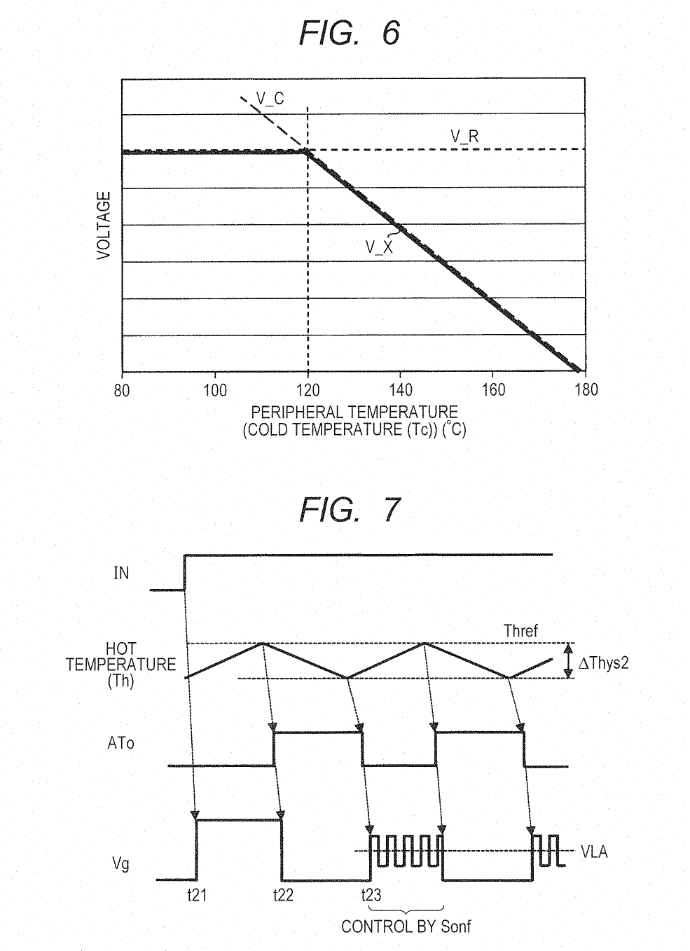

FIG. 6 is a view showing one example of a relation between the limited current signal and the peripheral temperature in the current limiting circuit of FIG. 5. As shown in FIG. 6, when the peripheral temperature (the cold temperature Tc) is lower than the boundary temperature (120° C.), the voltage level of the limited current signal V_X becomes a constant value based on the voltage V_R. This constant value controls the drive current when the temperature difference detecting signal DTo is asserted. On the other hand, when the cold temperature Tc is higher than the boundary temperature (120° C.), the voltage level of the limited current signal V_X becomes a value sequentially variable with the negative temperature characteristic, based on the voltage V_C. This value controls the drive current when the overtemperature detecting signal ATo is asserted.

FIG. 7 is a waveform chart showing a schematic operation example at detecting the overtemperature in the semiconductor device of FIG. 3. The waveform in FIG. 7 is almost the same as that shown in FIG. 14B. In FIG. 14B, however, at the timing t23, current limit is performed by controlling the gate voltage Vg to the voltage value VL2; in FIG. 7, the current limit is performed by switching-controlling the gate voltage Vg based on the on and off control signal Sonf. In this case, depending on the cold temperature Tc, a ratio of the on period and the off period in the on and off control signal Sonf fluctuates; therefore, the resultant mean value VLA of the gate voltages Vg is in accordance with the characteristic line of the limited current signal V_X as shown in FIG. 6. The operation at the temperature difference detection is also the same as that at the overtemperature detection.

### «Main Effect of First Embodiment»

As mentioned above, using the system of the first embodiment, it is possible to improve a balance between the safety for the temperature and the limit of the driving ability. More specifically describing, the drive current at the overtemperature detection is not limited to the constant lower current value IL2, regardless of the peripheral temperature like the case of FIG. 16, but is sequentially limited toward the current value IL2 depending on a rise of the peripheral temperature like the case of FIG. 4. As the result, as mentioned in FIGS. 18 and 19, it is possible to avoid such a situation that a small change of the cold temperature Tc would cause a great difference in the load driving state (lighting state of the light).

The current value IL2 is the limiting value required at the cold temperature Tc of 180° C. but the limiting value can be relaxed actually according as the cold temperature Tc gets lower. This is because the overshoot hardly occurs in the temperature change of the output transistor Qd according as the cold temperature Tc is getting lower, for example, in the hysteresis control as shown in FIG. 7 and as the result, even if the limiting value of the drive current is relaxed, the safety can be secured. By sequentially relaxing the limit of the drive current according to a drop of the peripheral temperature as shown in FIG. 4, the load driving ability can be obtained at the maximum within the range capable of securing the safety. For example, the load driving ability can be obtained more than by relaxing the limit of the drive current step by step. As the result, the IPD is enabled to drive many kinds of loads fully.

Here, the current limiting circuit ILMT is not necessarily restricted to the circuit system as shown in FIG. 5 but another circuit system can be used. Fr example, using the circuit as shown in FIG. 12, a system of controlling the gate voltage of the nMOS transistor MN1 with the voltage of reverse polarity of FIG. 6 (specifically, the voltage having the positive temperature characteristic with the temperature more than the boundary temperature) may be adopted.

However, from the viewpoint of the power consumption, high accuracy of current limit, and easy design, the circuit system as shown in FIG. 5 is preferable.

### Second Embodiment

### «Detail of Current Limiting Circuit and its Vicinity»

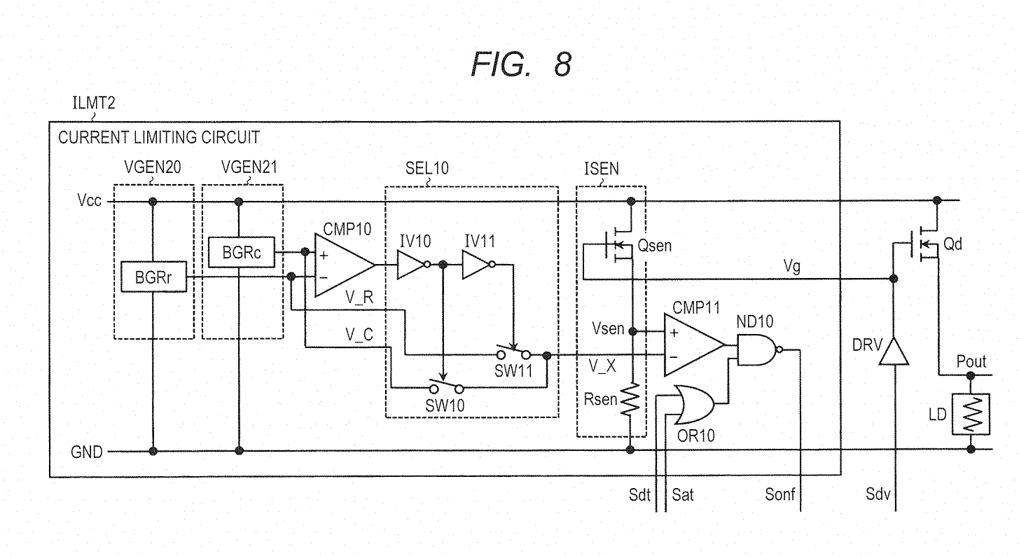

FIG. 8 is a circuit diagram showing the detailed constitutional example of the current limiting circuit of FIG. 3 in a semiconductor device according to a second embodiment of the invention. The current limiting circuit ILMT2 shown in FIG. 8 is different from that of the constitutional example of FIG. 5 in the structure of the voltage generating circuits VGEN20 and VGEN21. The voltage generating circuit VGEN20 includes a bandgap reference circuit BGRr and the voltage generating circuit VGEN21 includes a bandgap reference circuit BGRc. The bandgap reference circuits BGRr and BGRc are arranged, for example, adjacently to the diode Dcd (cold sensor) shown in FIG. 13.

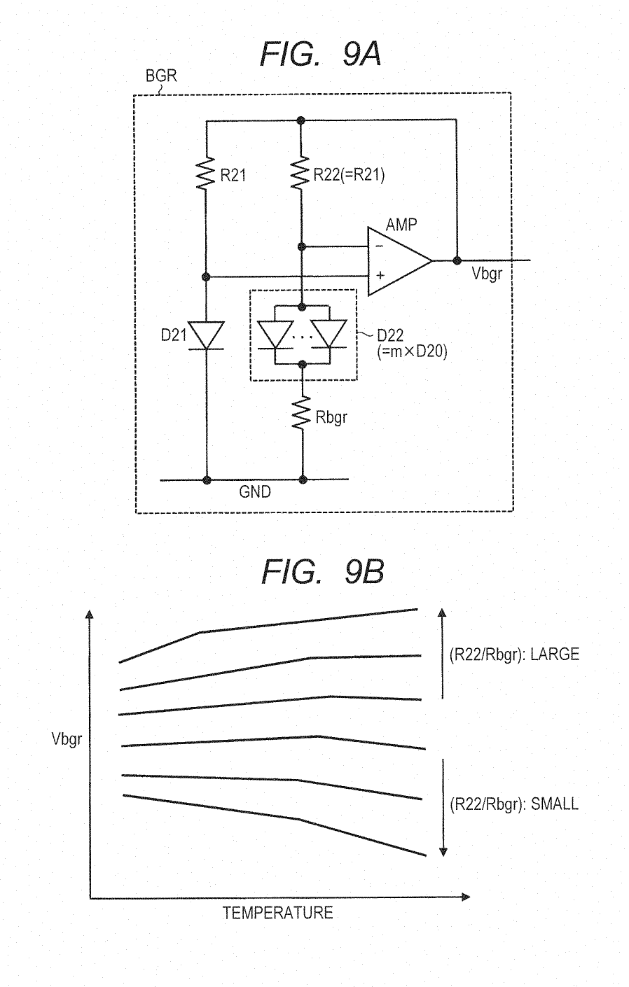

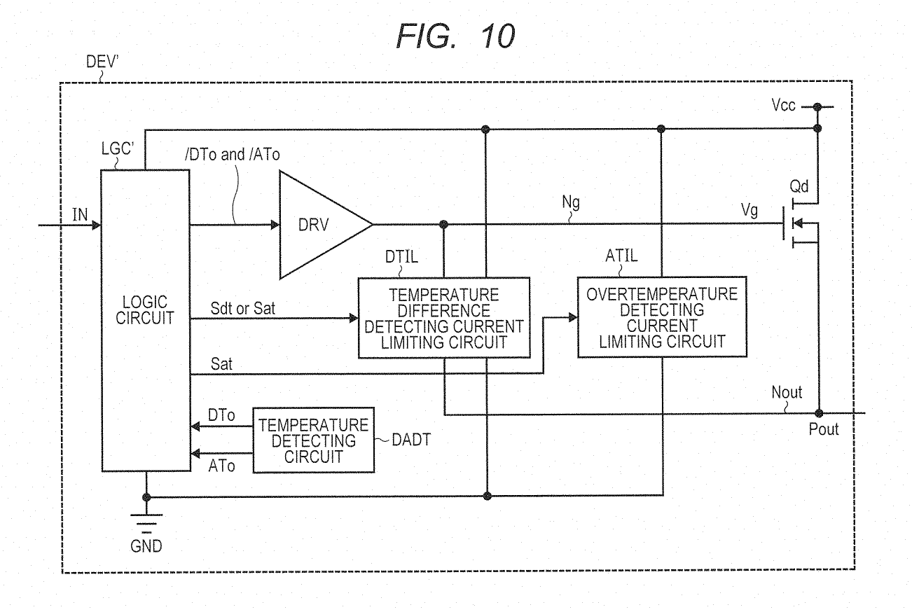

FIG. 9A is a circuit diagram showing the basic constitutional example of the bandgap reference circuit in FIG. 8, and FIG. 9B is a complementary view showing the operation example of FIG. 9A. The bandgap reference circuit BGR shown in FIG. 9A includes a resistance element R21, a diode D21 coupled to the above in series, a resistance element R22, a diode D22 and the bandgap resistance element Rbgr coupled to the above in series, and an amplifier circuit AMP. The resistance value of the resistance element R21 is equal to that of the resistance element R22, and the diode D22 has the element size m times as big as the diode D21.

The amplifier circuit AMP is formed in a negative feedback structure, to control the positive input node (+) and the negative input node (−) to have the same voltage. According to this, the current flowing in the diode D21 is equal to the current flowing in the diode D22. As the result, a difference value of the forward voltage ΔVbgr (=VT×ln(m)) (VT is a thermal voltage) between the diode D21 and the diode D22 occurs in the both ends of the bandgap resistance element Rbgr. Since the current flowing in the resistance element R22 is “ΔVbgr/Rbgr”, the output voltage Vbgr becomes “ΔVbgr+VF22+(ΔVbgr/Rbgr)×R22=VF22+ΔVbgr×(1+R22/Rbgr)” with the forward voltage of the diode D22 defined as VF22.

The “VF22” has the negative temperature characteristic and the “ΔVbgr×(1+R22/Rbgr)” has the positive temperature characteristic. Therefore, as shown in FIG. 9B, by adjusting the “R22/Rbgr”, the sensibility of the temperature characteristic in the output voltage Vbgr can be arbitrarily set. In FIG. 8, the output voltage Vbgr (namely, the voltage V_R) of the bandgap reference circuit BGRr is, for example, a constant value regardless of the temperature or has the negative temperature characteristic. On the other hand, the output voltage Vbgr (namely, the voltage V_C) of the bandgap reference circuit BGRc has the negative temperature characteristic with more sensibility than the bandgap reference circuit BGRr.

### «Main Effect of Second Embodiment»

As mentioned above, by using the system of the second embodiment, the same effect as in the case of the first embodiment can be obtained. Further, compared with the system of the first embodiment, there is the case of improving the high accuracy of the current limit. Concretely, the diode Dcd of FIG. 5 usually generates the voltage 0.4 V to 0.7 V depending on the temperature. On the other hand, the bandgap reference circuit BGRc can cope with a manufacturing variation better than the diode Dcd and generate a lower voltage V_C than the diode Dcd. When the voltage V_C can be reduced, the sense voltage Vsen can be reduced (the sense resistance element Rsen can be reduced in resistance). As the result, the current detection accuracy can be enhanced by the current mirror circuit (Qsen and Qd) and the higher accuracy of the current limit can be achieved. Further, since the bandgap reference circuit BGRc is compatible with the manufacturing variation, a variation in the current limit can be reduced. According to this, a high accuracy of the current limit can be achieved.

As mentioned above, by achieving the high accuracy in the current limit, it is possible to improve a balance between the safety for the temperature and the limit of the driving ability. The bandgap reference circuit is not restricted to the circuit of FIG. 9A, but may be various generally well-known circuits. Here, the voltage generating circuit VGEN20 having the bandgap reference circuit BGRr is used; however, instead of this, the voltage generating circuit VGEN10 having the resistance element Rref can be used, similarly to in the case of FIG. 5. Here, strictly speaking, the resistance element Rref has some temperature characteristic and because the manufacturing variation may be enlarged, the voltage generating circuit VGEN20 is preferably used from this viewpoint.

As set forth hereinabove, although the invention made by the inventor et al. has been concretely described based on the embodiments, the invention is not restricted to the embodiments, but various modifications can be made without departing from the spirit. For example, the above mentioned embodiments are specifically described for the sake of easy description of the invention and not restricted to the form including all the above mentioned components. One of the components in one embodiment may be replaced with a component in the other embodiment and further, a component in one embodiment may be added to the components in the other embodiment. One of the components in each of the embodiments can be added to, deleted from, or replaced with the other component/components.

For example, the semiconductor device in the embodiments can be widely applied not only to the electronic control unit ECU of FIG. 2 but also as a device for supplying power to various kinds of loads.

What is claimed is:

1. A semiconductor device comprising:
an output transistor which supplies a drive current to an external load;
a hot sensor which detects a temperature of the output transistor;
a cold sensor which detects a temperature of a position distant from the output transistor;
a temperature detecting circuit which asserts an overtemperature detecting signal when the temperature of the hot sensor rises more than a predetermined reference temperature and asserts a temperature difference detecting signal when a temperature difference between the hot sensor and the cold sensor is more than a predetermined reference temperature difference, and
a current limiting circuit which generates a limited current signal sequentially variable with negative temperature characteristic for the temperature of the cold sensor and limits a drive current of the output transistor to a current value depending on a signal level of the limited current signal when the overtemperature detecting signal is asserted.

2. The device according to claim 1,
wherein after asserting the overtemperature detecting signal, the temperature detecting circuit negates the overtemperature detecting signal when the temperature of the hot sensor is reduced by a first hysteresis temperature, and after asserting the temperature difference detecting signal, the above circuit negates the temperature difference detecting signal when the temperature difference is reduced by a second hysteresis temperature,
the above device further comprising:
a logic circuit which controls on and off the output transistor to control the temperature of the hot sensor to the reference temperature, using the overtemperature detecting signal and controls on and off the output transistor to control the temperature difference to the reference temperature difference, using the temperature difference detecting signal,
wherein the overtemperature detecting signal is asserted when the temperature of the cold sensor is higher than a boundary temperature,
wherein the temperature difference detecting signal is asserted when the temperature of the cold sensor is lower than the boundary temperature, and
wherein the limited current signal sequentially changes with the negative temperature characteristic for the temperature of the cold sensor in a temperature range in which the temperature of the cold sensor is higher than the boundary temperature.

3. The device according to claim 2,
wherein the limited current signal becomes a constant signal level for the temperature of the cold sensor in the temperature range in which the temperature of the cold sensor is lower than the boundary temperature, and
wherein the current limiting circuit limits the drive current of the output transistor to a current value depending on the signal level of the limited current signal when the temperature difference detecting signal is asserted.

4. The device according to claim 1,
wherein the cold sensor is a diode to which a constant current is supplied, and
wherein the current limiting circuit generates the limited current signal according to an output voltage of the cold sensor.

5. The device according to claim 1,
wherein the current limiting circuit generates the limited current signal by a bandgap reference circuit.

6. The device according to claim 1,
wherein the current limiting circuit includes
a current sense circuit which detects a drive current flowing in the output transistor and generates a voltage signal in proportion to a size of the drive current, and
a first comparator which compares the voltage signal from the current sense circuit with the limited current signal to control on and off the output transistor according to the comparison result.

7. The device according to claim 3,
wherein the current limiting circuit includes
a first voltage generating circuit which generates a constant voltage signal corresponding to the boundary temperature,
a second voltage generating circuit which generates a voltage signal having the negative temperature characteristic for the temperature of the cold sensor,
a second comparator which compares the voltage signal from the first voltage generating circuit with the voltage signal from the second voltage generating circuit, and
a selecting circuit which outputs the voltage signal from the first voltage generating circuit or the voltage signal from the second voltage generating circuit as the limited current signal, according to the comparison result of the second comparator.

8. The device according to claim 7,
wherein the current limiting circuit includes
a current sense circuit which detects a drive current flowing in the output transistor and generates a voltage signal in proportion to size of the drive current, and
a first comparator which compares the voltage signal from the current sense circuit with the limited current signal from the selecting circuit and controls on and off the output transistor according to the comparison result.

9. The device according to claim 7,
wherein the first voltage generating circuit includes a resistance element to which a constant current is supplied.

10. An electronic control unit comprising:
a microcontroller which realizes a predetermined function depending on a user;
a semiconductor device which drives an external load according to an instruction from the microcontroller; and
a wiring substrate on which the microcontroller and the semiconductor device are mounted,
wherein the semiconductor device includes
an output transistor which supplies a drive current to the load,
a hot sensor which detects a temperature of the output transistor,
a cold sensor which detects a temperature of a position distant from the output transistor,
a temperature detecting circuit which asserts an overtemperature detecting signal when a temperature of the hot sensor rises more than a predetermined reference temperature and asserts a temperature difference detecting signal when a temperature difference between the hot sensor and the cold sensor is more than a predetermined reference temperature difference, and
a current limiting circuit which generates a limited current signal sequentially variable with negative temperature characteristic for the temperature of the cold sensor and controls the drive current of the output transistor to a current value depending on a signal level of the limited current signal when the temperature detecting signal is asserted.

11. The unit according to claim 10,
wherein after asserting the overtemperature detecting signal, the temperature detecting circuit negates the overtemperature detecting signal when the temperature of the hot sensor is reduced by a first hysteresis temperature, and after asserting the temperature difference detecting signal, the above circuit negates the temperature difference detecting signal when the temperature difference is reduced by a second hysteresis temperature,
the above unit further comprising:
a logic circuit which controls on and off the output transistor to control the temperature of the hot sensor to the reference temperature, using the overtemperature detecting signal, and controls on and off the output transistor to control the temperature difference to the reference temperature difference, using the temperature difference detecting signal,
wherein the overtemperature detecting signal is asserted when the temperature of the cold sensor is higher than a boundary temperature,
wherein the temperature difference detecting signal is asserted when the temperature of the cold sensor is lower than the boundary temperature, and
wherein the limited current signal sequentially changes with the negative temperature characteristic for the temperature of the cold sensor in a temperature range in which the temperature of the cold sensor is higher than the boundary temperature.

12. The unit according to claim 11,
wherein the limited current signal becomes a constant signal level for the temperature of the cold sensor in the temperature range in which the temperature of the cold sensor is lower than the boundary temperature, and
wherein the current limiting circuit limits the drive current of the output transistor to a current value depending on the signal level of the limited current signal when the temperature difference detecting signal is asserted.

13. The unit according to claim 10,
wherein the cold sensor is a diode to which a constant current is supplied, and
wherein the current limiting circuit generates the limited current signal according to the output voltage of the cold sensor.

14. The unit according to claim 10,
wherein the current limiting circuit generates the limited current signal by a bandgap reference circuit.

15. The unit according to claim 10,
wherein the load is a light for vehicle.
